(19) United States
(12) Patent Application Publication
(10) Pub. No.: US 2025/0172886 A1
(43) Pub. Date: May 29, 2025

(54) STATUS MONITORING AND REPORTING FOR ULTRAVIOLET LIGHT SOURCES

(71) Applicant: Cymer, LLC, San Diego, CA (US)

(72) Inventors: Spencer Ryan Williams, San Diego, CA (US); Christopher James Stevens, Valley Center, CA (US); Kent Steiner, Balsam Grove, NC (US); Ye Jiang, San Diego, CA (US); Jung Yoon Shin, Yongin-si (KR)

(21) Appl. No.: 18/844,213

(22) PCT Filed: Mar. 6, 2023
(86) PCT No.: PCT/US2023/014657

§ 371 Date: Sep. 5, 2024

Related U.S. Application Data
(60) Provisional application No. 63/488,085, filed on Mar. 2, 2023.
(60) Provisional application No. 63/318,749, filed on Mar. 10, 2022.

(51) Int. Cl. G03F 7/00; G03F 7/20; G06F 3/0482

(52) U.S. Cl. CPC G03F 7/70991; G03F 7/2002; G03F 7/70508; G03F 7/70975; G06F 3/0482

(57) ABSTRACT

A computing device including a display screen is at a photolithography exposure facility. The facility includes one or more photolithography exposure apparatuses. The computing device is configured to display on the display screen: a status region including one or more status indicators, each status indicator associated with an ultraviolet (UV) light source configured to supply light to a respective photolithography exposure apparatus of the one or more photolithography apparatuses; a graph region including one or more graphs, each graph displaying information relating to the one or more status indicators; and a filtering region including one or more menu items selectable to control the information displayed in the status region and/or in the one or more graphs.

### CROSS REFERENCE TO RELATED APPLICATIONS

This application claims priority to U.S. application Ser. No. 63/318,749, filed Mar. 10, 2022, titled STATUS MONITORING AND REPORTING FOR ULTRAVIOLET LIGHT SOURCES; and U.S. Application No. 63/488,085, filed Mar. 2, 2023, titled STATUS MONITORING AND REPORTING FOR ULTRAVIOLET LIGHT SOURCES, both of which are incorporated herein in their entireties by reference.

### TECHNICAL FIELD

This disclosure relates to status monitoring and reporting for an ultraviolet light source, particularly for an ultraviolet light source providing light to a lithography apparatus.

### BACKGROUND

Light, which can be laser radiation, that is used for semiconductor photolithography is typically supplied by a system referred to as a light source. These light sources produce ultraviolet radiation as a series of pulses at specified repetition rates, for example, in the range of about 500 Hz to about 6 kHz. Performance and uptime are critical to the users of such light sources at photolithography exposure facilities, given the high values imparted during steps, such as lithography steps, of the semiconductor manufacturing process.

### SUMMARY

In some general aspects, a computing device is at a photolithography exposure facility, the facility including one or more photolithography exposure apparatuses. The computing device includes a display screen. The computing device is configured to display on the display screen: a status region including one or more status indicators, each status indicator associated with an ultraviolet (UV) light source configured to supply light to a respective photolithography exposure apparatus of the one or more photolithography apparatuses; a graph region including one or more graphs, each graph displaying information relating to the one or more status indicators; and a filtering region including one or more menu items selectable to control the information displayed in the status region and/or in the one or more graphs.

Implementations can include one or more of the following features. For example, the computing device can be configured to display status indicators including a first status indicator configured to indicate that the associated UV light source requires no action, a second status indicator configured to indicate that the performance of the associated UV light source should be monitored, and a third status indicator configured to indicate that the associated UV light source requires maintenance. The computing device can be configured to display status indicators including a fourth status indicator configured to indicate that the status of the associated UV light source cannot be assessed.

The computing device can be configured to display on the display screen in the status region, for each of the one or more light source status indicators, a selectable set of subsystem status indicators, the subsystem status indicators associated with respective subsystems of the respective UV light source. “Selectable” herein means activatable or “choose-able” by a user at the computing device. Implementations of “selectable” can include touch screens with touch-activated icons or other symbols, activated such as by a finger press, a stylus or other tool or the like. Other implementations of “selectable” can include icons or other symbols on the display selectable and activatable by an input device such as a mouse, touch pad, and the like. Selectable items and the display screen may even take the form of buttons or similar user-input devices, including for example an array of buttons capable of displaying and/or changing an icon or symbol displayed thereon. The computing device can be configured to display on the display screen in the filtering region one or more additional menu items selectable to control which subsystem status indicators are included in the selectable set of subsystem status indicators. The computing device can be further configured to selectably display on the display screen, in response to a user selection of the one or more menu items, additional detailed data relating to the one or more light sources or to the one or more photolithography apparatuses. The additional detailed data can comprise exposure data for the one or more light sources or the one or more photolithography apparatuses. The additional detailed data can comprise exposure data including sub-wafer-level exposure data for the one or more light sources or the one or more photolithography apparatuses. The UV light source can be a deep ultraviolet (DUV) light source. The computing device can be configured to display subsystem status indicators including a first subsystem status indicator configured to indicate that the associated subsystem requires no action, a second subsystem status indicator configured to indicate that the performance of the associated subsystem should be monitored, and a third subsystem status indicator configured to indicate that the associated subsystem requires maintenance. The computing device can be configured to display subsystem status indicators including a fourth subsystem status indicator configured to indicate that the status of the associated subsystem cannot be assessed.

The facility can include two or more photolithography exposure apparatuses and wherein the status region includes two or more status indicators.

In other general aspects, a computing device is at a photolithography exposure facility, the facility including one or more photolithography exposure apparatuses. The computing device includes a display screen. The computing device is configured to display on the display screen: a status region including one or more light source status indicators, each light source status indicator associated with an ultraviolet (UV) light source configured to supply light to a respective photolithography exposure apparatus of the one or more photolithography apparatuses.

Implementations can include one or more of the following features. For example, the computing device can be configured to display on the display screen a graph region including one or more graphs, each graph displaying information relating to the one or more light source status indicators. The computing device can be configured to display on the display screen a filtering region including one or more menu items selectable to control the information displayed in a graph of the one or more graphs. The one or more light source status indicators can be a selected set of light source status indicators and the one or more menu items can be selectable to control which light source status indicators are included in the selected set of light source status indicators.

The computing device can be configured to display on the display screen in the status region, for each of the one or more light source status indicators, a selectable set of subsystem status indicators, the subsystem status indicators associated with respective subsystems of the respective UV light source. The computing device can be configured to display on the display screen in the filtering region one or more menu items selectable to control which subsystem status indicators are included in the selectable set of subsystem status indicators.

In other general aspects, a computer-implemented procedure includes: displaying a first status indicator within a first view of a user interface, the first status indicator configured to indicate that an ultraviolet (UV) light source requires no action, the status indicator being indicative of the operation of a UV light source configured to supply UV light to a photolithography exposure apparatus; in response to a first prediction using data relating one or more subsystems of the UV light source, the first prediction relating to the performance of the UV light source, changing the display from the first status indicator to a second status indicator within the first view of the user interface, the second status indicator configured to indicate that the performance of the UV light source should be monitored; and in response to a second prediction using data relating to one or more subsystems of the UV light source, the second prediction relating to the performance of the UV light source, changing the display from the first status indicator or the second status indicator to a third status indicator within the first view of the user interface, the third status indicator configured to indicate that the UV light source requires maintenance.

Implementations can include one or more of the following features. For example, the procedure can also include, in response to a status change relating to one or more subsystems of the UV light source, changing the display from the first status indicator, the second status indicator, or the third status indicator to a fourth status indicator within the first view of the user interface, the fourth status indicator configured to indicate that the status of the UV light source cannot be assessed. The procedure can include: displaying two or more first status indicators within the first view of a user interface, each of the two or more first status indicators configured to indicate that an associated UV light source of two or more UV light sources requires no action, each of the first status indicators being indicative of the operation of the associated UV light source, each associated UV light source configured to supply UV light to an associated UV lithography apparatus; in response to a first prediction using data relating one or more subsystems of a respective UV light source of the two or more UV light sources, the first prediction relating to the performance of the respective UV light source, changing the display from the first status indicator associated with the respective UV light source to a second status indicator within the first view of the user interface, the second status indicator associated with the respective UV light source and configured to indicate that the performance of the respective UV light source should be monitored; and in response to a second prediction using data relating to one or more subsystems of a respective UV light source of the two or more UV light sources, the second prediction relating to the performance of the respective UV light source, changing the display from the first status indicator associated with the respective UV light source or the second status indicator associated with the respective UV light source to a third status indicator within the first view of the user interface, the third status indicator associated with the respective UV light source and configured to indicate that the respective UV light source requires maintenance. The procedure can include, in response to a status change relating to one or more subsystems of a respective UV light source of the two or more UV light sources, changing the display from the first status indicator of the respective UV light source, the second status indicator of the respective UV light source, or the third status indicator of the respective UV light source to a fourth status indicator within the first view of the user interface, the fourth status indicator associated with the respective UV light source and configured to indicate that the status of the respective UV light source cannot be assessed.

The UV light source can be a deep ultraviolet (DUV) light source. The DUV wavelength range typically includes wavelengths from, for example, about 100 nanometers (nm) to about 400 nm. The UV light source optionally can be an extreme ultraviolet (EUV) light source including wavelengths within the range of 4-20 nm, for example within the range of 13-14 nm, such as a wavelength of 13.5 nm or about 13.5 nm. EUV radiation can alternatively have a wavelength of less than 10 nm, for example within the range of 4-10 nm such as wavelengths of 6.7 nm or 6.8 nm.

In other general aspects, a computer program product includes at least one non-transitory computer-readable storage medium having computer-executable program code instructions stored therein, the computer-executable program code instructions including program code instructions configured to, when executed by a processor of a computing system, cause the computing system to: display a first status indicator of a group of status indicators within a first view of a user interface, the first status indicator configured to indicate that an ultraviolet (UV) light source requires no action, status indicators of the group of status indicators being indicative of the operation of the UV light source, the UV light source configured to supply UV light to a photolithography exposure apparatus; in response to receipt of a first prediction using data relating one or more subsystems of a UV light source, the first prediction relating to the performance of the UV light source, change the display within the first view of the user interface from the first status indicator to a second status indicator of the group of status indicators, the second status indicator configured to indicate that the performance of the UV light source should be monitored; and in response to receipt of a second prediction using data relating one or more subsystems of the UV light source, the second prediction relating to the performance of the UV light, change the display from the first status indicator or the second status indicator to a third status indicator within the first view of the user interface, the third status indicator configured to indicate that the UV light source requires maintenance.

Implementations can include one or more of the following features. Program code instructions can be configured to, when executed by a processor of a computing system, cause the computing system to, in response receipt of information representing a status change relating to one or more subsystems of the UV light source, change the display within the first view of the user interface from the first status indicator, the second status indicator, or the third status indicator to a fourth status indicator of the group of status indicators, the fourth status indicator configured to indicate that the status of the UV light source cannot be assessed. The UV light source can be a deep ultraviolet (DUV) light source.

In additional aspects, a system includes a computing device at a photolithography exposure facility, the facility comprising one or more photolithography exposure apparatuses, the computing device comprising a display screen, the computing device being configured to display on the display screen: a status region including one or more status indicators, each status indicator associated with an ultraviolet (UV) light source configured to supply light to a respective photolithography exposure apparatus of the one or more photolithography apparatuses; a graph region including one or more graphs, each graph displaying information relating to the one or more status indicators; and a filtering region including one or more menu items selectable to control the information displayed in the status region and/or in the one or more graphs; and, configured for communication in connection with the computing device at the photolithography exposure facility. The system also includes a computing device at a maintenance provider facility, the computing at the maintenance provider facility being configured to display on a display screen: a status region equivalent to the status region, including the one or more status indicators associated with an ultraviolet (UV) light source configured to supply light to a respective photolithography exposure apparatus of the one or more photolithography apparatuses; a graph region equivalent to the graph region, including one or more graphs displaying information relating to the one or more status indicators; and a filtering region equivalent to the filtering region, including one or more menu items selectable to control the information displayed in the status region and/or in the one or more graphs.

The computing device at the photolithography exposure facility can be further configured to selectably display on the display screen, in response to a user selection of the one or more menu items, additional detailed data relating to the one or more light sources or to the one or more photolithography apparatuses including sub-wafer-level exposure data for the one or more light sources or the one or more photolithography apparatuses. The computing device at the maintenance provider facility can be configured to not receive or display sub-wafer-level exposure data for the one or more light sources or the one or more photolithography apparatuses. The UV light source can be a deep ultraviolet (DUV) light source.

The details of one or more implementations are set forth in the accompanying drawings and the description below. Other features will be apparent from the description and drawings, and from the claims.

### DRAWING DESCRIPTION

FIG. 1A is a block diagram of a computing device having a display screen, together with one or more light sources and one or more associated photolithography exposure apparatuses in a photolithography exposure facility.

FIG. 1B is a diagram of items displayed on the display screen of the computing device of FIG. 1A.

FIG. 1C is a diagram of a status region displayed on the display screen of the computing device of FIG. 1A.

FIG. 2 is a diagram of light source status indicators which can be displayed in the status region of FIG. 1C.

FIG. 3 is a diagram showing light source subsystem status indicators which can be displayed in the status region of FIG. 1C.

FIG. 4 is a schematic diagram showing a light source and associated photolithography apparatus, the light source having light source subsystems that provide signals and/or data to an intermediate processor that provides status information to the computing device of FIG. 1A.

FIG. 5 is a schematic diagram of an implementation of a light source of FIG. 1A.

FIG. 6 is a schematic diagram of an implementation of a photolithography exposure apparatus of FIG. 1A.

FIG. 7 is a schematic diagram of an implementation of the computing device of FIG. 1A.

FIGS. 8 and 8A are flow charts showing processes for implementing aspects of the status region of FIG. 1C.

FIG. 9A is an example of the status region of FIG. 1C, showing examples of status indicators.

FIG. 9B is an example of a graph displaying information relating to the status indicators of FIG. 9A.

### DETAILED DESCRIPTION

In an aspect of the present disclosure, a display screen on a computing device at a photolithography exposure facility is disclosed, the facility comprising one or more photolithography exposure apparatuses, the computing device being configured to display on the display screen information concerning the status of one or more ultraviolet (UV) light sources configured to supply light to the photolithography exposure apparatuses.

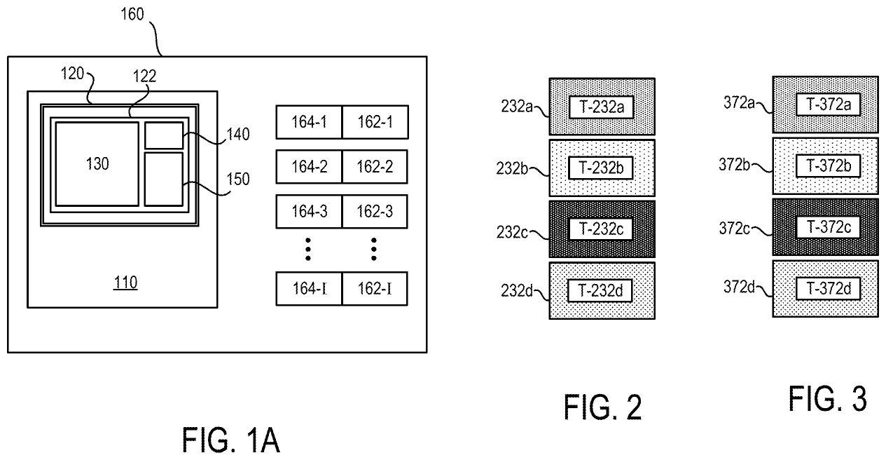

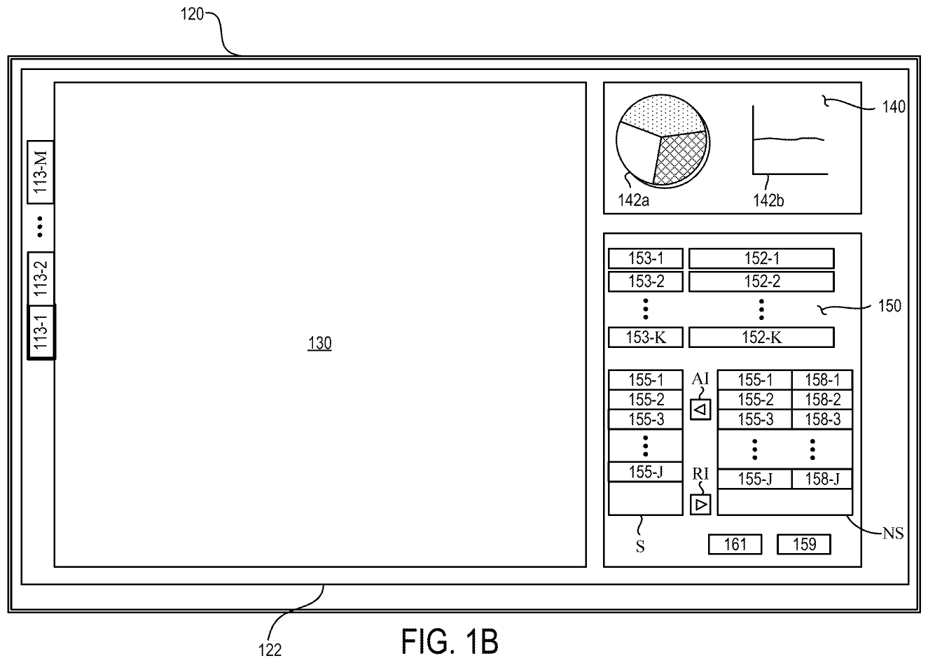

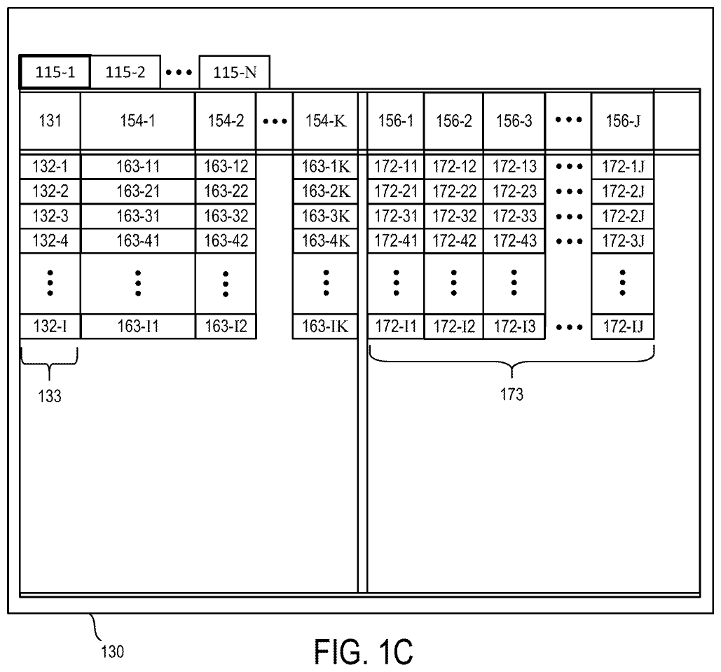

Specifically, with reference to FIGS. 1A, 1B, and 1C, a computing device 110 is positioned in or at a photolithography exposure facility 160. The computing device 110 can be in the form of a desktop computer, a laptop computer, or a handheld device, such as, and including a cell phone, a paddle, a tablet computer, a server, or other processor, and the like. The computing device 110 may be integrated into equipment or other furnishings (not shown) within the facility 160, and may be located in a central location and/or positioned at a respective one (or one or more respective ones) of the photolithography apparatuses or light sources discussed below. The computing device 110 can have wired and/or wireless communication capabilities.

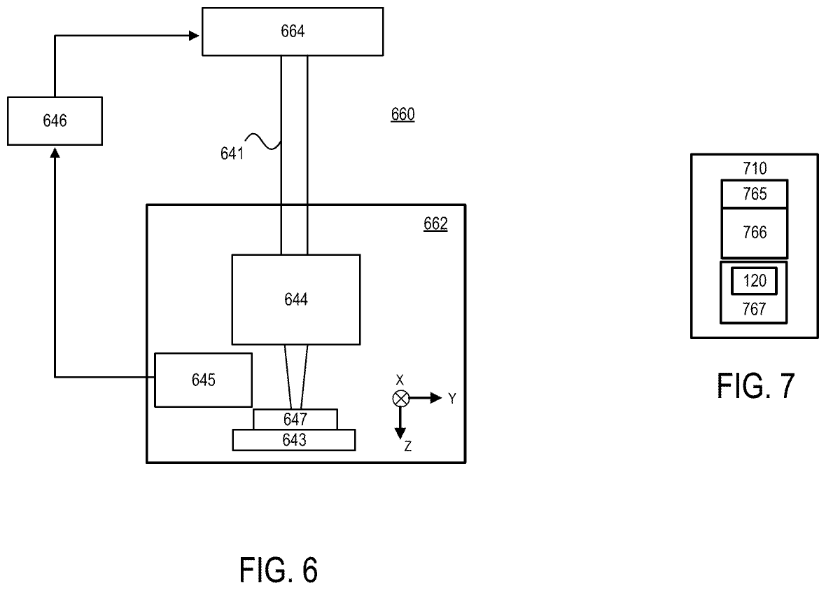

The facility 160 includes one or more photolithography exposure apparatuses 162-i, where “i” is the set of numbers 1, 2, . . . I and “I” here represents the total count of the one or more apparatuses 162-i. While four photolithography exposure apparatuses 162-1, 162-2, 162-3, 162-I are shown in FIG. 1A, it is possible for the facility 160 to include fewer than four or more than four apparatuses 162-i. The computing device 110 includes a display screen 120, and the computing device 110 is configured to display on the display screen, as part of a graphical user interface (GUI) 122: (1) a status region 130 including one or more status indicators 132-i (see FIG. 1C), each status indicator 132-i associated with an ultraviolet (UV) light source 164-i configured to supply light to a respective photolithography exposure apparatus 162-i of the one or more photolithography apparatuses 162-i; (2) a graph region 140 including one or more graphs 142a,142b (see FIG. 1B), each graph 142a, 142b displaying information relating to the one or more status indicators 132-i; and (3) a filtering region 150 including one or more menu items 152-k (FIG. 1B) selectable to control the information displayed in the status region 130 and/or in the one or more graphs 142a, 142b. The “k” here represents the set of numbers 1, 2, . . . K, and “K” here represents the total count of the one or more menu items 152-k. The selectable menu items 152-k may be selected through a direct touch on the GUI 122 by a user of the computing device 110. In other implementations, the selectable menu items 152-k may be selected through button presses or other physical interactions with the computing device 110 by a user of the computing device 110. A status indicator column heading 131 can be included above the status indictors 132-i, if desired, using the word “status” or some other designation such as “light source status” or “light source score.” Light supplied by a respective light source 164-i is used by a respective associated photolithography exposure apparatus 162-i to expose patterns in or on a respective wafer or succession of wafers (not shown in FIG. 1A, but see FIG. 6 and the associated description below).

As shown in FIG. 1B, a menu item label 153-k associated with the one or more menu items 152-k can be displayed adjacent thereto in the filtering region 150. The menu item labels 153-k and the associated one or more menu items 152-k can be groupings and/or properties of light sources 164-i. Selecting from the menu items 152-k controls which one or ones of the one or more light sources 164-i at or in the facility 160 will have an associated status indicator 132-i displayed in the status region 130. The menu item labels 153-k (displayed in the filtering region 150) can correspond to column headings 154-k, which are displayed in the status region 130 above columns of light-source-identifying-information items 163-ik. The items 163-ik can be items such as user-defined groups of light sources, user-or manufacturer-assigned light source names or numbers, light source serial numbers, light source model names and/or numbers, light source software types and/or versions, light source operating wavelengths, lithography apparatus identifiers of the associated lithography apparatuses, even the last update time of the respective light source status indicator 132-i, and so forth, and symbols or other indicators of these groups or categories can be used for the menu item labels 153-k and the column headings 154-k.

With reference to FIG. 2, the status indicators 132-i, which the computing device 110 is configured to display on the display screen 120, can be selected from a group that includes a first status indicator 232a, a second status indicator 232b, and a third status indicator 232c. For example, the first status indicator 232a is configured to indicate that the associated UV light source 164-i requires no action, the second status indicator 232b is configured to indicate that the performance of the associated UV light source 164-i should be monitored, and the third status indicator 232c is configured to indicate that the associated UV light source 164-i requires maintenance. The status indicators 132-i can indicate their respective statuses by displaying different symbols representing each status, for example, by color coding as depicted by the shading of FIG. 2, or by use of numbers or letters, or the like. In one implementation, color coding can be used, such as green for no action (232a), yellow or amber for monitoring needed (232b), and red or orange or the like for maintenance required (232c). In some implementations, a text block T-232a, T-232b, or T-232c can be used to spell out the color used for greater accessibility of the displayed information. The status indicators 132-i, which the computing device 110 is configured to display on the display screen 120, can also include a fourth status indicator 232d configured to indicate that the status of the associated UV light source 164-i cannot be assessed. If color coding is used, for example, the fourth status indicator 232d could be displayed as grey, and a text block T-232d can also be used. The fourth status indicator 232d can be used, for example, when the UV light source 164-i or a subsystem thereof has had a recent step-change in performance or physical condition, such as when maintenance or significant adjustment has recently been performed. The fourth status indicator 232d can then revert to one of the first, second, or third status indicators 232a, 232b, 232c after sufficient time has passed and/or sufficient performance stability has been achieved.

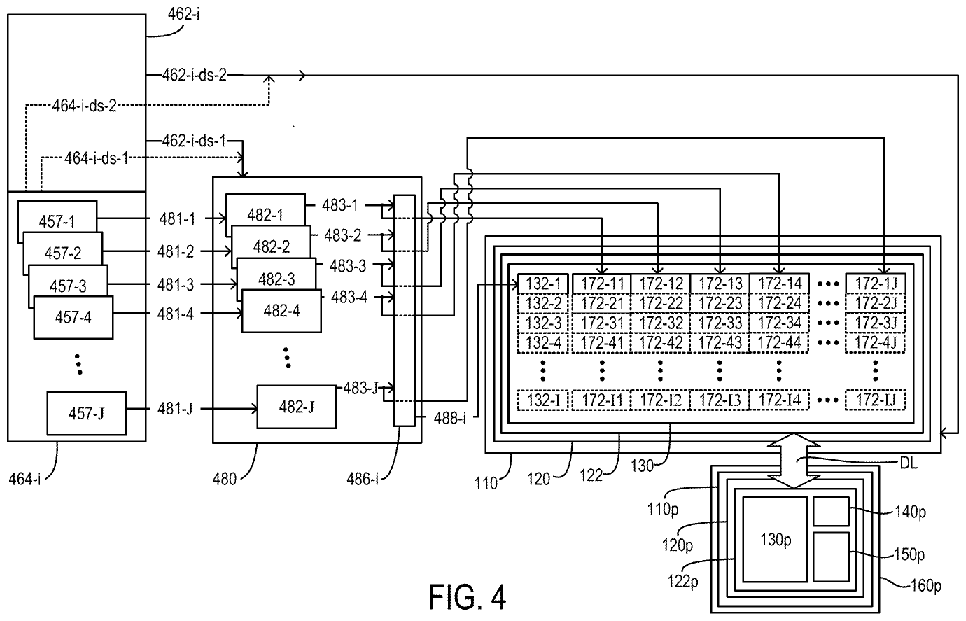

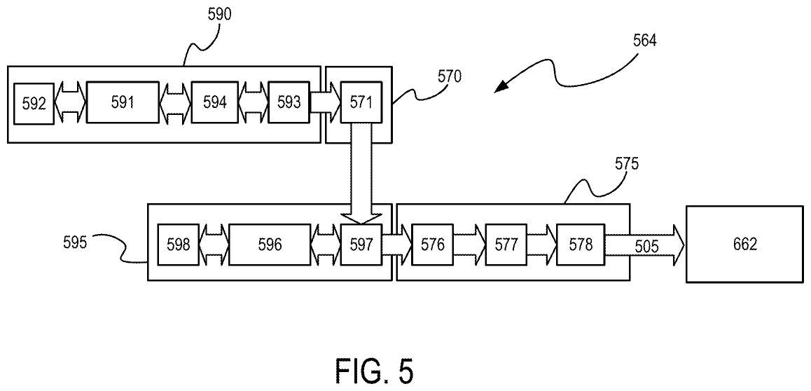

With reference again to FIGS. 1A, 1B, and 1C, the computing device 110 can be configured to display on the display screen 120 in the status region 130, for each of the one or more light source status indicators 132-i, a selectable set 173 of subsystem status indicators 172-ij, the subsystem status indicators 172-ij (see FIG. 1C) associated with respective subsystems (not shown in FIGS. 1A-1C, but see FIGS. 4 and 5 described below) of the respective UV light source 164-i. Here “j” is the set of numbers 1, 2, . . . J, and “J” here represents the total count of subsystem status indicators 172-ij in the selectable set 173.

The computing device 110 can also be configured to display on the display screen 120 in the filtering region 150 one or more additional menu items 155-j selectable to control which subsystem status indicators 172-ij are included in the selectable set 173. The menu items 155-j can be arranged in two regions, a “selected” region S and a non-selected region NS. Menu items 155-j in the selected region S can be moved to the non-selected region by highlighting the items, then selecting such as by clicking or pressing an “add” icon AI. Menu items 155-j in the non-selected region NS can be moved to the selected region by highlighting the items, then selecting such as by clicking or pressing a “remove” icon RI. The set currently in the selected region S can be applied to the status region 130 by selecting such as by clicking or pressing an “apply” icon 159. A default setting of all items 155-j included in the selected region S and displayed in the status region 130 can be accessed by selecting such as by pressing or clicking a default icon 161. When considered across both regions S and NS, “j” is the set of numbers 1, 2, . . . . J, and “J” here represents the total count of additional menu items available for selection by a user for inclusion in the selectable set 173.

The additional menu items 155-j can correspond to subsystems of the respective light sources for which status indicators 132-i are or can be displayed. Thus, a user may select (1) those light sources of the one or more light sources 164-i for which status indicators 132-i are displayed (via menu items 152-k) and (2) those subsystems (not shown in FIGS. 1A-1C) of those light sources for which status indicators 172-ij are displayed. Subsystem status indicator column headings 156-1 to 156-K correspond to the selected menu items 155-j and serve to identify the subsystem type for which subsystem status indicators 172-ij are displayed in respective column below.

The additional menu items 155-j, which can be used to select subsystems whose status will be displayed, can also be paired with a status selector 158-j, which can select which status indicators will be displayed for a given selected item 155-j from among first, second third, and fourth status indicators.

With reference to FIG. 3, the status indicators 172-ij, which the computing device 110 is configured to display for the selectable set 173, can include a first status indicator 372a configured to indicate that an associated UV light source subsystem no action, a second status indicator 372b configured to indicate that the performance of the associated UV light source subsystem should be monitored, and a third status indicator 372c configured to indicate that the associated UV light source subsystem requires maintenance. The status indicators 372a, 372b, 372c can indicate their respective statuses by displaying different symbols representing each status, by color coding as depicted by the shading of the figure, or by use of numbers or letters, or the like. In one implementation, color coding may be used, such as green for no action (372a), yellow or amber for monitoring needed (372b), and red or orange or the like for maintenance required (372c). A text block T-372a, T-372b, T-372c may be used to spell out the color used for greater accessibility of the displayed information. The status indicators 172-j which the computing device 110 is configured to display for the selectable set 173 can also include a fourth status indicator 372d configured to indicate that the status of the associated UV light source subsystem cannot be assessed. If color coding is used, for example, the fourth status indicator 372d could be displayed as grey, and a text block T-372d can also be used. The fourth status indicator 372d can be used, for example, when the UV light source subsystem has had a recent step-change in performance or physical condition, such as when maintenance or significant adjustment has recently been performed. The status indicator 372d can then revert to one of the first, second, or third status indicators after sufficient time has passed and/or sufficient performance stability has been achieved.

Again with reference to FIGS. 1A-1C, in summary, the computing device 110 is provided at the photolithography exposure facility 100, which includes one or more photolithography exposure apparatuses 162-i. The computing device 110 includes the display screen 120, and the computing device 110 is configured to display, on the display screen, the status region 130 including one or more status indicators 132-i, each status indicator 132-i associated with an ultraviolet (UV) light source 164-i configured to supply light to a respective photolithography exposure apparatus of the one or more photolithography exposure apparatuses 162-i.

The computing device 110 can be configured to display, on the display screen 120, the graph region 140 including one or more graphs 142a, 142b. The computing device 110 can be configured to display, on the display screen 120, the filtering region 150 including one or more menu items 152-k selectable to control the information displayed in a graph of the one or more graphs 142a, 142b and/or in the status region 130. The one or more light source status indicators 132-i can be a selected set 133 of light source status indicators, and the one or more menu items 152-k can selectable to control which light source status indicators 132-i are included in the selected set 133.

The computing device 110 can be configured to display, on the display screen 120, in the status region 130, for each of the one or more light source status indicators 132-i, a selectable set 173 of subsystem status indicators 172-ij, the subsystem status indicators 172-ij associated with respective subsystems (not shown in FIGS. 1A-1C, but see FIGS. 4 and 5 discussed below) of the respective UV light source 164-i.

The computing device 110 can be configured to display, on the display screen 120 and in the filtering region 150, one or more additional menu items 155-j selectable to control which subsystem status indicators 172-ij are included in the selectable set 173 of subsystem status indicators.

The display screen 120 provides a graphical user interface (GUI) 122 at the photolithography exposure facility 160. This GUI 122 provides a user (such as an engineer) at the facility 160 with ready access to curated data about the UV light sources 164-i in an easily digested form. Moreover, the GUI 122 can tell the user at the facility 160 how each UV light source 164-i is doing, including enabling the user to see prioritized information that includes analyses of that information that is useful for the user to make decisions regarding operation of each photolithography exposure apparatus 162-i. The light source status indicators 132-i allow a user to essentially instantaneously recognize the presence of any significant light source performance issue. The selectable subsystem status indicators 172-ij allow the user to quickly see which subsystem(s) may be contributing to any issue.

In implementations, GUI 122 including the status region 130, or the status region 130, the graph region 140, and the filtering region 150, can be the “landing page” or first-up (for example, “home”) screen upon opening or initializing a system delivering all kinds of data relating to the one or more light sources 164-i, thus providing an overview of the relative performance of health of all or any desired light source 164-i before more detailed data is accessed, such as by selection of tabs from among tab from among tabs 113-1 through 113-M, or from among 115-1 through 115-N, for example. The user is accordingly better able to see the “big picture” of the overall operations of the one or more light sources 164-i. More detailed data available through the GUI 122 and shown on screens selectable by tabs such as tabs 113-1 through 113-M or 115-1 tabs through 115-N or by other means can include, among other things, exposure data (not shown) provided from the respective light source 164-i or the associated respective lithography apparatus 162-i. The exposure data (not shown) can include wafer-level exposure data (exposure data for each wafer) and/or sub-wafer-level exposure data (defined as individual exposure data for individual sub-regions of a wafer).

FIG. 4 is a schematic diagram showing a representation of a light source 164-i in the form of light source 464-i having light source subsystems 457-j. With reference to FIG. 4, the subsystems 457-j or sensors or systems associated therewith (not shown) provide signals and/or data 481-j useful in determining the performance and/or state of health of the subsystems 457-j. An intermediate processor 480, which may be separate as shown in the figure, or can optionally be incorporated into computing device 110 and can also optionally be distributed over multiple physical processors and/or devices, includes a subsystem evaluator 482-j associated with each subsystem 457-j and the corresponding signals and/or data 481-j. The subsystem evaluator 482-j uses the signals and/or data, such as by combining, comparing, weighing and the like, to determine a status of the associated subsystem 457-j, and to output status information 483-j relating to the associated subsystem 457-j to a light source evaluator 486-i. The light source evaluator uses the status information 483-j, such as by combining, comparing, weighing and the like, to determine a status of the associated light source 464-i, and to output status information 488-i to the computing device 110 and/or to the status region 130 of the GUI 122 displayed on the display area 120 thereof. Also, the status information 483-j associated with the respective light source subsystems 457-j can be passed directly, if desired, or as selected by a user, to the computing device 110 and/or to the status region 130 thereof to provide for display of subsystem status indicators 172-11 through 172-1J.

Although for convenience in FIG. 4, each subsystem 457-j of light source 464-i is shown having a one-to-one relationship with the corresponding signals or data 481-j, in some implementations, the corresponding signals or data 481-j for each subsystem 457-j can come from multiple sources, rather than and/or in addition to the respective subsystem 457-j, including, for example, other subsystems. Also, in other implementations, an individual signal and/or data source may contribute to or be included in more than one of the corresponding signals or data 481-1 to 481-J.

Also, for convenience in FIG. 4, only one light source 464-i is shown, and only one corresponding light source evaluator 486-i, but in the case of a photolithographic exposure facility 160 having a number of light sources I, in some or even most or all implementations, there would also be I number of light source evaluators employed, each receiving multiple feeds of subsystem status information corresponding multiple subsystem evaluators associated with the subsystems 457-j of the respective light source 464-i, and each producing and transmitting respective status information 488-i to the computing device 110 and/or to the status region 130, allowing display of I number of rows of light source status indicators 132-i. The additional rows of status indicators 132-i beyond the first are shown in the display screen 120 of FIG. 4 in dashed outline in reflection of the fact that corresponding light sources 464-i and light source evaluators and their associated devices and communications are not shown in FIG. 4. Likewise, the multiple rows of subsystem status indicators 172-ij beyond the first are shown in the display screen 120 in reflection of the fact that corresponding light sources 464-i with related subsystems 457-j and subsystem evaluators 482-j are not shown in FIG. 4.

As further shown in FIG. 4, a photolithography apparatus 462-i configured to receive light from the light source 464-i can provide a data stream 462-i-ds-1 to the intermediate processor 480. The data stream 462-i-ds-1 can be used as input by one or more of the subsystem evaluators 482-1 through 482-J and/or by the light source evaluator 486-i in the processor 480. The data stream 462-i-ds-1 can include exposure data at the wafer level (defined as individual exposure data relating to an individual wafer exposed by the photolithography apparatus 462-i, and not to sub-regions of the wafer) and at higher (aggregated or less specific) levels, for example. As an alternative to data stream 462-i-ds-1 from the light source 462-i, a data stream 464-i-ds-1 (represented in part by a dashed line in FIG. 4) from the light source 464-i can be configured to provide equivalent data. The photolithography apparatus 462-i configured to receive light from the light source 464-i can also or alternatively provide a data stream 462-i-ds-2 to the computing device 110. The data stream 462-i-ds-2 can include exposure data at the wafer level (defined as individual exposure data relating to an individual wafer exposed by the photolithography apparatus 462-i, and not to sub-regions of the wafer) and/or at other levels, including at the sub-wafer-level, for example. This data can be made available in the GUI 122, for example, on selectable screens (not shown) selectable by tabs such as tabs 113-1 through 113-M or 115-1 tabs through 115-N or by other means, as discussed and shown above with respect to FIGS. 1B and 1C. As an alternative to data stream 462-i-ds-2 from the light source 462-i, a data stream 464-i-ds-2 (represented in part by a dashed line in FIG. 4) from the light source 464-i can be configured to provide equivalent data.

As further shown in the diagram of FIG. 4, according to additional aspects of the present disclosure, a system can be provided including a computing device at a photolithography exposure facility 110, the facility comprising one or more photolithography exposure apparatuses 464-i, the computing device comprising a display screen 120, the computing device being configured to display on the display screen 120: a GUI 122 including a status region 130 including one or more status indicators 132-1 through 132-I (FIG. 1B), each status indicator 132-1 through 132-I associated with an ultraviolet (UV) light source 464-1 through 464-I (only one of which, 464-i, shown in FIG. 4, see FIG. 1A), configured to supply light to a respective photolithography exposure apparatus 464-i of the one or more photolithography exposure apparatuses 464-1 through 464-I (see FIG. 1A); a graph region 140 (not shown in FIG. 4, see FIG. 1B) including one or more graphs 142a, 142b (FIG. 1B), each graph displaying information relating to the one or more status indicators 131-1 through 132-I (FIG. 1C); and a filtering region 150 (not shown in FIG. 4, see FIG. 1B) including one or more menu items 152-1 through 152-K and/or 155-1 through 155-J (FIG. 1B) selectable to control the information displayed in the status region 130 and/or in the one or more graphs 142a, 142b; and a computing device 110p at a maintenance provider facility 160p. The maintenance provider facility 160p can be a central facility or database or the like at which performance of light sources in a photolithography exposure facility 160 or in multiple such facilities is monitored. The maintenance provider facility 160p can be as simple as working location of an individual maintenance person in possession of the computing device 110p, which can be a portable computing device. In this context, portable means having a weight, size, and construction suitable for being carried by hand by a user at the maintenance provider facility 160p. The maintenance provider facility 160p can also be a location or station or one or more stations or locations within the photolithography exposure facility 160, such as a station and/or interface attached to an individual light source or photolithography apparatus, for example, a location of a “paddle” attached to an individual light source or photolithography apparatus. The computing device 110p can be in the form of a desktop computer, a laptop computer, or a handheld device, such as and including a cell phone, a paddle, a tablet computer, a server, or other processor, and the like. The computing device 110p can be integrated into equipment or other furnishings, and can have wireless and/or wired communication capability. The computing device 110p at the maintenance provider facility 160p is configured to display on a display screen 120, a GUI 122p having a status region 130p equivalent to the status region 130 at the computer 110 at the photolithography facility, namely, a status region 130p equivalent to the status region 130 (see status region 130 of FIGS. 1A through 1C for the details that follow), including the one or more status indicators 132-1 through 132-I each associated with a respective UV light source 164-i of the UV light sources 164-1 through 164-I (FIG. 1A) configured to supply light to a respective photolithography exposure apparatus 162-i of the one or more photolithography apparatuses 162-1 through 162-I (FIG. 1A); a graph region 140p equivalent to the graph region 140 (FIGS. 1A, 1B), including one or more graphs 142a and 142b (FIG. 1B) displaying information relating to the one or more status indicators 132-1 through 132-I; and a filtering region 150p equivalent to the filtering region 150 (FIG. 1B), including one or more menu items 152-1 through 152-K and/or 155-1 through 155-J (FIG. 1B) selectable to control the information displayed in the status region 130p and/or in the one or more graphs 142a, 142b. Note that “equivalent to” as used herein encompasses “identical to.” Implementations can include one or more of the following.

The data necessary to provide the GUI 122p at the computer 110p equivalent to the GUI 122 at the computer 110 can be transmitted over a data link DL which may include any useful data transmission infrastructure and/or method. Other arrangements are possible. The data link DL can alternatively run between the intermediate processor 480 and the computer 110p, rather than between the GUI 122 and the GUI 122p as shown, for example. The data link can be uni- or bi-directional. Also for example, both computers 110 and 110p can receive the relevant data in parallel, from a source such as intermediate computer 480 or some other intermediate source. What is significant in this aspect is that the computer 110p at the at the maintenance provider facility is configured for communication in connection with the computing device at the photolithography exposure facility, such as in one of the ways mentioned, so that a GUI 122p with an equivalent status region to the status region 130 of the GUI 122 is displayed on a screen 120p at the computing device 110p at a maintenance provider facility. A maintenance provider can then see, simultaneously or essentially simultaneously, the same status display and status data as that shown at the photolithography facility, allowing for easy communication and coordination regarding performance of one or more light sources and/or for easy planning and scheduling of potential maintenance actions. The computer at a maintenance provider facility can be a computer at a maintenance shop or maintenance management center, a computer or a laptop or cell phone in a maintenance station, cart, or vehicle, a laptop or cell phone in the hands of a maintenance technician, or the like.

The computing device 110 at the photolithography exposure facility can be further configured to selectably display on the display screen 120 as a part of the GUI 122 additional detailed data relating to one or more light sources 464-i or to one or more photolithography apparatuses 462-i, including sub-wafer-level exposure data for the one or more light sources or the one or more photolithography apparatuses. The computing device 110p at the maintenance provider facility 160p can be configured not to receive or display sub-wafer-level exposure data for the one or more light sources 464-i or the one or more photolithography apparatuses 462-i, such as by not receiving the data stream 462-i-ds2 or by not receiving the data stream 464-i-ds2 or any corresponding data from data link DL, for example, as sub-wafer-level exposure data can be held as proprietary data by the operator of a photolithographic exposure facility such as photolithographic exposure facility 160 (FIG. 1A), or by a customer of the operator the facility 160.

FIG. 5 shows a schematic diagram of an implementation 564 of any of the light sources 164-i or 464-i. The light source 564 is a dual-stage pulsed light source that produces a pulsed light beam 505, which is directed to a photolithography exposure apparatus 662. The photolithography exposure apparatus 662 corresponds to the respective photolithography exposure apparatus 162-i associated with that particular light source 164-i or 464-i. The light source 564 includes a solid state or gas discharge master oscillator (MO) system 590, a power amplification (PA) system such as a power ring amplifier (PRA) system 595, relay optics 570, and an optical output subsystem 575. This light source 564 is a deep UV (DUV) light source 564 and the pulsed light beam 505 has a wavelength in the DUV wavelength range, which includes wavelengths from, for example, about 100 nanometers (nm) to about 400 nm.

The MO system 590 can include, for example, an MO chamber module 591, in which electrical discharges between electrodes (not shown) can cause lasing gas discharges in a lasing gas to create an inverted population of high energy molecules, such as including argon, krypton, or xenon to produce relatively broad band radiation that is line narrowed to a relatively very narrow bandwidth and center wavelength selected in a line narrowing module (‘LNM’) 592. The MO system 590 can also include an MO output coupler (MO OC) 593, which can include a partially reflective mirror, forming, with a reflective grating (not shown) in the LNM 592, an oscillator cavity in which the MO system 590 oscillates to form a seed output pulse. The MO system 590 can also include a line-center analysis module (LAM) 594. The LAM 594 can include, for example, an etalon spectrometer for fine wavelength measurement and a coarser resolution grating spectrometer. The LAM 594 can be source of signals and/or data for one or more of the corresponding signals or data 481-1 to 481-J of FIG. 4, for example.

The relay optics 570 shown in FIG. 5 can include an MO wavefront engineering box (WEB) 571 that serves to redirect the output of the MO system 590 toward the PA system 595, and can include, for example, beam expansion with, for example, a multi prism beam expander (not shown) and coherence busting, for example, in the form of an optical delay path (not shown).

The PA system 595 includes a PRA chamber module 596, which is also an oscillator, for example, formed by injection of the output light beam from the MO system 590 and output coupling optics (not shown) that can be incorporated into a PRA WEB 597 and can be redirected back through a gain medium in the chamber 596 by way of a beam reverser 598. The PRA WEB 597 can incorporate a partially reflective input/output coupler (not shown) and a maximally reflective mirror for the nominal operating wavelength (which can be at around 193 nm for an ArF system) and one or more prisms. The PA system 595 optically amplifies the output light beam from the MO system 590.

The optical output subsystem 575 can include a bandwidth analysis module (BAM) 576 at the output of the PA system 595 that receive the output light beam of pulses from the PA system 595 and picks off a portion of the light beam for metrology purposes, for example, to measure the output bandwidth and pulse energy. The output light beam of pulses then passes through an optical pulse stretcher module (OPuS) 577 and an output combined autoshutter metrology module (CASMM) 578, which can also be the location of a pulse energy meter which can also be a source of signals and/or data for one or more of the corresponding signals or data 481-1 to 481-J of FIG. 4. One purpose of the OPuS 577 can be to convert a single output pulse into a pulse train. Secondary pulses created from the original single output pulse can be delayed with respect to each other. By distributing the original laser pulse energy into a train of secondary pulses, the effective pulse length of the light beam can be expanded and at the same time the peak pulse intensity reduced.

The light source 564 is made up of subsystems 457-j. Each of the components (such as the MO chamber 591, the LNM 592, the MO WEB 571, the PRA chamber 596, the PRA WEB 597, the OPuS 577, the BAM 576) of the light source 564 are subsystems 457-j. The overall performance of the light source 564 is the result of the respective and combined performance of these individual subsystems 457-j making up the light source 564.

FIG. 6 shows a schematic diagram of an implementation 660 of a photolithography exposure facility 160 including a single photolithography exposure apparatus 662 (which corresponds to one of the photolithography exposure apparatuses 162-i of FIG. 1A). The facility 660 includes a light source 664 (corresponding to any of light sources 164i) that provides a light beam 641 to the photolithography exposure apparatus 662. The photolithography exposure apparatus 662 processes a wafer 647 received by a wafer holder or stage 643. The light beam 641 is a pulsed light beam that includes pulses of light separated from each other in time. The photolithography exposure apparatus 662 includes a projection optical system 644 through which the light beam 641 passes prior to reaching the wafer 647, and a metrology system 645. The metrology system 645 can include, for example, a camera or other device that is able to capture an image of the wafer 647 and/or the light beam 641 at the wafer 647, or an optical detector that is able to capture data that describes characteristics of the light beam 641, such as intensity of the light beam 641 at the wafer 647 in the x-y plane. The photolithography exposure apparatus 662 can be a liquid immersion system or a dry system. The facility 660 can also include a control system 646 associated with the light source 664 and the photolithography exposure apparatus 662, the control system 646 configured to control the light source 664 and/or the photolithography exposure apparatus 662.

Microelectronic features are formed on the wafer 647 by, for example, exposing a layer of radiation-sensitive photoresist material on the wafer 647 with the light beam 641. In some implementations, the projection optical system 644 includes a slit, a mask, and a projection objective, which includes a lens. The light beam 641 enters the projection optical system and impinges on the slit, and at least some of the beam 641 passes through the slit. In one example, the slit is rectangular and shapes the light beam 641 into an elongated rectangular shaped light beam. A pattern is formed on the mask, and the pattern determines which portions of the shaped light beam 641 are transmitted by the mask and which are blocked by the mask. The design of the pattern is determined by the specific microelectronic circuit design that is to be formed on the wafer 647. The portions of the shaped light beam that are transmitted by the mask form an aerial image in the x-y plane in the wafer 647. The aerial image is the intensity pattern formed by the light that reaches the wafer 647 after interacting with the mask.

FIG. 7 shows a schematic diagram of an implementation 710 of the computing device 110. The computing device 710 includes an electronic processor 765, an electronic storage 766, and an I/O interface 767. The electronic processor 765 includes one or more processors suitable for the execution of a computer program such as a general or special purpose microprocessor, and any one or more processors of any kind of digital computer. Generally, an electronic processor receives instructions and data from a read-only memory, a random-access memory, or both. The electronic processor 765 may be any type of electronic processor.

The electronic storage 766 may be volatile memory, such as RAM, or non-volatile memory. In some implementations, the electronic storage 766 includes non-volatile and volatile portions or components. The electronic storage 766 may store data and information that is used in the operation of the computing device 710, components of the computing device 710, and/or systems controlled by the computing device 710. The information may be stored in, for example, a look-up table or a database.

The electronic storage 766 may store instructions, for example as a computer program, that, when executed, cause the processor 765 to communicate with components in the computing device 710, or with other processors, whether internal or external to the computing device 710.

The I/O interface 767 is any kind of electronic interface that allows the computing device 710 to receive and/or provide data and signals with an operator and the processor 765. The I/O interface 767 includes the display area 120, and may include one or more additional display areas, keyboards, and other communications interfaces.

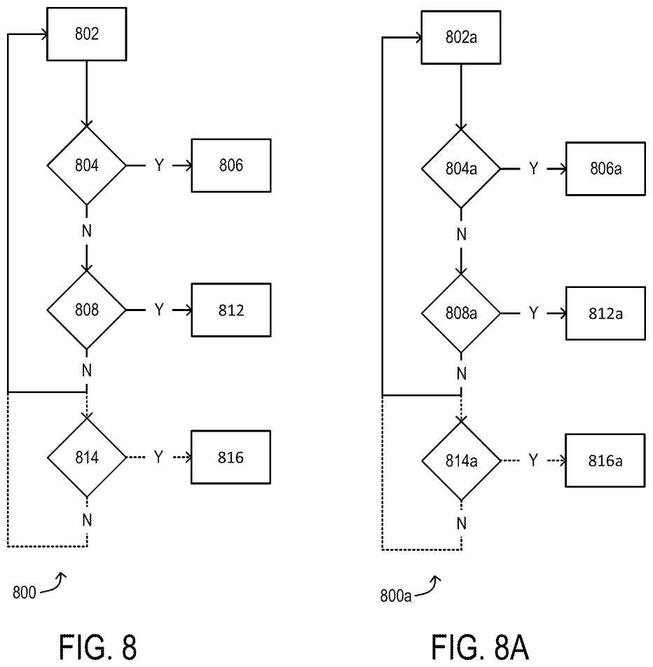

With reference to FIG. 8, in an aspect of the present disclosure, a computer-implemented procedure 800 includes (1) displaying a first status indicator within a first view of a user interface (802), the first status indicator configured to indicate that an ultraviolet (UV) light source requires no action, the first status indicator being indicative of the operation of a UV light source configured to supply UV light to a photolithography exposure apparatus; (2) in response to a first prediction using data relating one or more subsystems the UV light source (804), the first prediction relating to the performance of the respective UV light source, changing the display from the first status indicator to a second status indicator within the first view of the user interface (806), the second status indicator configured to indicate that the performance of the UV light source should be monitored; and (3) in response to a second prediction using data relating one or more subsystems of the UV light source (808), the second prediction relating to the performance of the respective UV light source, changing the display from the first status indicator or the second status indicator to a third status indicator within the first view of the user interface (812), the third status indicator configured to indicate that the UV light source requires maintenance. The predictions at 804 and/or 808 can be made by light source evaluator 486-i, described above with reference to FIG. 4.

In an implementation, the procedure 800 can further include, in response to a determination (814) of a status change relating to one or more subsystems of the UV light source, such as a step change in performance or a physical change such as performance of a maintenance operation or a significant adjustment of the subsystem, changing the display from the first status indicator, the second status indicator, or the third status indicator to a fourth status indicator within the first view of the user interface (816). The fourth status indicator is configured to indicate that the status of the UV light source cannot be assessed.

In implementations as represented in FIG. 8A, the procedure 800 or a procedure 802a can further include: (1) displaying two or more first status indicators within the first view of a user interface (802a), each of the two or more first status indicators configured to indicate that an associated UV light source of two or more UV light sources requires no action, each of the first status indicators being indicative of the operation of the associated UV light source, each associated UV light source configured to supply UV light to an associated UV lithography apparatus; (2) in response to a first prediction using data relating one or more subsystems of a respective UV light source of the two or more UV light sources (804a), the first prediction relating to the performance of the respective UV light source, changing the display from the first status indicator associated with the respective UV light source to a second status indicator within the first view of the user interface (806a), the second status indicator associated with the respective UV light source and configured to indicate that the performance of the respective UV light source should be monitored; and (3) in response to a second prediction using data relating one or more subsystems of a respective UV light source of the two or more UV light sources (808a), the second prediction relating to the performance of the respective UV light source, and changing the display from the first status indicator associated with the respective UV light source or the second status indicator associated with the respective UV light source to a third status indicator within the first view of the user interface (812a), the third status indicator associated with the respective UV light source and configured to indicate that the respective UV light source requires maintenance. Even more than two light sources may also be used according to additional aspects of this procedure 800a.

In some implementations, the procedure 802a can also include: in response to a detection 814a of a status change relating to one or more subsystems of a respective UV light source of the two or more two or more UV light sources, changing the display from the first status indicator of the respective UV light source, the second status indicator of the respective UV light source, or the third status indicator of the respective UV light source to a fourth status indicator within the first view of the user interface (816a), the fourth status indicator associated with the respective UV light source and configured to indicate that the status of the respective UV light source cannot be assessed.

In another aspect of the present disclosure, a computer program product includes at least one computer-readable storage medium, such as electronic storage medium 766, in non-transitory form, having computer-executable program code instructions stored therein.

The computer-executable program code instructions include program code instructions configured to, when executed by a processor such as processor 765 of a computing system such as computing device 710, cause the computing system to: (1) display a first status indicator 232a of a group of status indicators 232a-232c within a first view of a user interface (such as on the display 120 of the GUI 122), the first status indicator 232a configured to indicate that an ultraviolet (UV) light source 164-i, 464-i requires no action, the status indicators 232a-232c being indicative of the operation of the UV light source 164-i, 464-i that is configured to supply UV light to a photolithography exposure apparatus 162-i, 662; (2) in response to receipt of a first prediction (804) using data relating to one or more subsystems 457-i of the UV light source 164-i, 464-i, the first prediction relating to the performance of the UV light source 164-i, 464-i, change the display from the first status indicator 232a to a second status indicator 232b within the first view of the user interface (such as on the display 120 of the GUI 122), the second status indicator 232b configured to indicate that the performance of the UV light source should be monitored; and (3) in response to receipt of a second prediction (808) using data relating the one or more subsystems 457-i of the UV light source 164-i, 464-i, the second prediction (808) relating to the performance of the UV light source 164-i, 464-i, change the display from the first status indicator 232a or the second status indicator 232b to a third status indicator 232c within the first view of the user interface (such as on the display 120 of the GUI 122), the third status indicator configured to indicate that the UV light source 164-i, 464-i requires maintenance.

In some implementations of the computer program product, the program code instructions are configured to, when executed by a processor such as processor 765 of a computing system such as computing device 710, cause the computing system (such as the computing device 110) to, in response receipt of information representing a status change relating to one or more subsystems 457-i of the UV light source 164-i, 464-i, change the display from the first status indicator 232a, the second status indicator 232b, or the third status indicator 232c to a fourth status indicator 232d within the first view of the user interface (such as on the display 120 of the GUI 122), the fourth status indicator 232d configured to indicate that the status of the UV light source 164-i, 464-i cannot be assessed.

In any of the procedures and computing devices or systems above, the UV light source can be, specifically, a deep UV (DUV) light source, such as the DUV light source shown in FIG. 5.

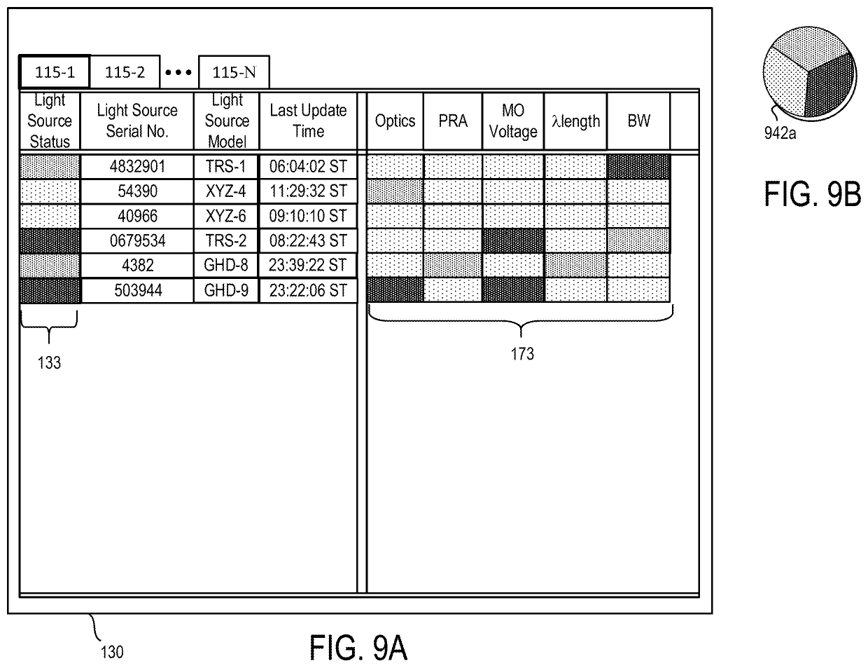

FIG. 9A is an example of the status region of FIG. 1C, showing examples of status indicators 132-i (in the selected set 133) and of subsystem status indicators 172-ij (in the selected set 173), both in the form of variously shaded or colored regions as discussed above with respect to FIGS. 2 and 3. The status indicator column heading 131 is in the form of the label “Light Source Status”, and to the right of it are various column headings 154-k of light-source-identifying-information items 163-ik, with columns of example items shown underneath. The column headings 154-k include “Light Source Serial No.” (with example serial numbers displayed in the column below), “Light Source Model” (with light source model designations, such as “TRS-1”, “TRS-2” and so forth displayed in the column below) and “Last Update Time” (with times displayed in the column below, in this case in the format “HH:MM:SS ST” where H stands hours digits in a 24-hour clock, MM stands for minutes digits, and SS stands for seconds digits). Optics, PRA, MO Voltage, λlength, and BW are example subsystem status indicator column headings 156-i indicating the respective subsystem for which respective subsystem status indicators 172-ij are displayed in a column below the heading. For example, the heading “λlength” of the subsystem status indicator column headings 156-i heads a column of status indicators displaying the statuses of the wavelengths of respective pulsed light beams produced by respective light sources identified by the respective light-source-identifying-information items 163-ik in the respective row, while the heading 156-i “BW” heads a column of status indicators displaying the statuses of the bandwidth(s) of respective pulsed light beams produced by the respective light sources identified by the respective light-source-identifying-information items 163-ik in the respective row.

FIG. 9B is an example of a graph displaying information relating to the status indicators 132-i of FIG. 9A. Specifically in this case, as shown in FIG. 9B, a pie chart representation 942a is displayed of the relative proportion of each type of status shown by the status indicators 132-i of the selected set 133 of FIG. 9A. Three status indicators 132-i are shown in this example in FIG. 9A. The three status indicators 132-9 are: a dark-shade indicator, a medium-shade indicator, and light-shade indicator. These status indicators can correspond to red, amber, and green colors, for example, or to various shades or symbols which can be used to indicate statuses such as no action needed, monitoring needed, and maintenance needed, for example. The total number of status indicators shown in FIG. 9A is six. Each of the three status indicators shown in FIG. 9A occurs twice, such that each of the three status indicators represents one-third of the total. This is represented in the displayed pie chart by shading or coloring pie chart sections to match the shading or coloring of the status indicators, and by proportionally sizing of the sections to match the proportion of the total status indicators of each status indicator. In the case shown, the pie chart is accordingly divided into three equal sections, one of each shade.

The aspects and implementations can be further described using the following enumerated examples:

1. A computing device at a photolithography exposure facility, the facility comprising one or more photolithography exposure apparatuses, the computing device comprising a display screen, the computing device being configured to display on the display screen:
a status region including one or more status indicators, each status indicator associated with an ultraviolet (UV) light source configured to supply light to a respective photolithography exposure apparatus of the one or more photolithography apparatuses;
a graph region including one or more graphs, each graph displaying information relating to the one or more status indicators; and
a filtering region including one or more menu items selectable to control the information displayed in the status region and/or in the one or more graphs.

2. The computing device of example 1 wherein the computing device is configured to display status indicators comprising a first status indicator configured to indicate that the associated UV light source requires no action, a second status indicator configured to indicate that the performance of the associated UV light source should be monitored, and a third status indicator configured to indicate that the associated UV light source requires maintenance.

3. The computing device of example 2 wherein the computing device is configured to display status indicators comprising a fourth status indicator configured to indicate that the status of the associated UV light source cannot be assessed.

4. The computing device of example 1, wherein the computing device is configured to display on the display screen in the status region, for each of the one or more light source status indicators, a selectable set of subsystem status indicators, the subsystem status indicators associated with respective subsystems of the respective UV light source.

5. The computing device of example 4 wherein the computing device is configured to display on the display screen in the filtering region one or more additional menu items selectable to control which subsystem status indicators are included in the selectable set of subsystem status indicators.

6. The computing device of example 4 wherein the computing device is configured to display subsystem status indicators comprising a first subsystem status indicator configured to indicate that the associated subsystem requires no action, a second subsystem status indicator configured to indicate that the performance of the associated subsystem should be monitored, and a third subsystem status indicator configured to indicate that the associated subsystem requires maintenance.

7. The computing device of example 6 wherein the computing device is configured to display subsystem status indicators comprising a fourth subsystem status indicator configured to indicate that the status of the associated subsystem cannot be assessed.

8. The computing device of example 1 wherein the facility comprises two or more photolithography exposure apparatuses and wherein the status region includes two or more status indicators.

9. A computing device at a photolithography exposure facility, the facility comprising one or more photolithography exposure apparatuses, the computing device comprising a display screen, the computing device being configured to display on the display screen:
a status region including one or more light source status indicators, each light source status indicator associated with an ultraviolet (UV) light source configured to supply light to a respective photolithography exposure apparatus of the one or more photolithography apparatuses.

10. The computing device of example 9 wherein the computing device is configured to display on the display screen a graph region including one or more graphs, each graph displaying information relating to the one or more light source status indicators.

11. The computing device of example 10 wherein the computing device is configured to display on the display screen a filtering region including one or more menu items selectable to control the information displayed in a graph of the one or more graphs.

12. The computing device of example 11 wherein the one or more light source status indicators are a selected set of light source status indicators and the one or more menu items are selectable to control which light source status indicators are included in the selected set of light source status indicators.

13. The computing device of example 9 wherein the computing device is configured to display on the display screen in the status region, for each of the one or more light source status indicators, a selectable set of subsystem status indicators, the subsystem status indicators associated with respective subsystems of the respective UV light source.

14. The computing device of example 13 wherein the computing device is configured to display on the display screen in the filtering region one or more menu items selectable to control which subsystem status indicators are included in the selectable set of subsystem status indicators.

15. The computing device of example 1 wherein the computing device is further configured to selectably display on the display screen, in response to a user selection of the one or more menu items, additional detailed data relating to the one or more light sources or to the one or more photolithography apparatuses.

16. The computing device of example 15 wherein the additional detailed data comprises exposure data for the one or more light sources or the one or more photolithography apparatuses.

17. The computing device of example 15 wherein the additional detailed data comprises exposure data including sub-wafer-level exposure data for the one or more light sources or the one or more photolithography apparatuses.

18. The computing device of example 1 wherein the UV light source is a deep ultraviolet (DUV) light source.

19. A computer-implemented procedure comprising:
displaying a first status indicator within a first view of a user interface, the first status indicator configured to indicate that an ultraviolet (UV) light source requires no action, the status indicator being indicative of the operation of a UV light source configured to supply UV light to a photolithography exposure apparatus;
in response to a first prediction using data relating one or more subsystems of the UV light source, the first prediction relating to the performance of the UV light source, changing the display from the first status indicator to a second status indicator within the first view of the user interface, the second status indicator configured to indicate that the performance of the UV light source should be monitored; and
in response to a second prediction using data relating to one or more subsystems of the UV light source, the second prediction relating to the performance of the UV light source, changing the display from the first status indicator or the second status indicator to a third status indicator within the first view of the user interface, the third status indicator configured to indicate that the UV light source requires maintenance.

20. The procedure of example 19 further comprising, in response to a status change relating to one or more subsystems of the UV light source, changing the display from the first status indicator, the second status indicator, or the third status indicator to a fourth status indicator within the first view of the user interface, the fourth status indicator configured to indicate that the status of the UV light source cannot be assessed.

21. The procedure of example 19 further comprising:
displaying two or more first status indicators within the first view of a user interface, each of the two or more first status indicators configured to indicate that an associated UV light source of two or more UV light sources requires no action, each of the first status indicators being indicative of the operation of the associated UV light source, each associated UV light source configured to supply UV light to an associated UV lithography apparatus;
in response to a first prediction using data relating one or more subsystems of a respective UV light source of the two or more UV light sources, the first prediction relating to the performance of the respective UV light source, changing the display from the first status indicator associated with the respective UV light source to a second status indicator within the first view of the user interface, the second status indicator associated with the respective UV light source and configured to indicate that the performance of the respective UV light source should be monitored; and
in response to a second prediction using data relating to one or more subsystems of a respective UV light source of the two or more UV light sources, the second prediction relating to the performance of the respective UV light source, changing the display from the first status indicator associated with the respective UV light source or the second status indicator associated with the respective UV light source to a third status indicator within the first view of the user interface, the third status indicator associated with the respective UV light source and configured to indicate that the respective UV light source requires maintenance.

22. The procedure of example 21 further comprising, in response to a status change relating to one or more subsystems of a respective UV light source of the two or more UV light sources, changing the display from the first status indicator of the respective UV light source, the second status indicator of the respective UV light source, or the third status indicator of the respective UV light source to a fourth status indicator within the first view of the user interface, the fourth status indicator associated with the respective UV light source and configured to indicate that the status of the respective UV light source cannot be assessed.

23. The procedure of example 19 wherein the UV light source is a deep ultraviolet (DUV) light source.

24. A computer program product comprising at least one non-transitory computer-readable storage medium having computer-executable program code instructions stored therein, the computer-executable program code instructions comprising program code instructions configured to, when executed by a processor of a computing system, cause the computing system to:
display a first status indicator of a group of status indicators within a first view of a user interface, the first status indicator configured to indicate that an ultraviolet (UV) light source requires no action, status indicators of the group of status indicators being indicative of the operation of the UV light source, the UV light source configured to supply UV light to a photolithography exposure apparatus;
in response to receipt of a first prediction using data relating one or more subsystems of a UV light source, the first prediction relating to the performance of the UV light source, change the display within the first view of the user interface from the first status indicator to a second status indicator of the group of status indicators, the second status indicator configured to indicate that the performance of the UV light source should be monitored; and
in response to receipt of a second prediction using data relating one or more subsystems of the UV light source, the second prediction relating to the performance of the UV light, change the display from the first status indicator or the second status indicator to a third status indicator within the first view of the user interface, the third status indicator configured to indicate that the UV light source requires maintenance.

25. The computer program product of example 24 wherein the program code instructions are configured to, when executed by a processor of a computing system, cause the computing system to, in response receipt of information representing a status change relating to one or more subsystems of the UV light source, change the display within the first view of the user interface from the first status indicator, the second status indicator, or the third status indicator to a fourth status indicator of the group of status indicators, the fourth status indicator configured to indicate that the status of the UV light source cannot be assessed.

26. The computer program product of example 24 wherein the UV light source is a deep ultraviolet (DUV) light source.

27. A system comprising:
a computing device at a photolithography exposure facility, the facility comprising one or more photolithography exposure apparatuses, the computing device comprising a display screen, the computing device being configured to display on the display screen:
   a status region including one or more status indicators, each status indicator associated with an ultraviolet (UV) light source configured to supply light to a respective photolithography exposure apparatus of the one or more photolithography apparatuses;
   a graph region including one or more graphs, each graph displaying information relating to the one or more status indicators; and
a filtering region including one or more menu items selectable to control the information displayed in the status region and/or in the one or more graphs; and, configured for communication in connection with the computing device at the photolithography exposure facility:
   a computing device at a maintenance provider facility, the computing at the maintenance provider facility being configured to display on a display screen:
      a status region equivalent to the status region, including the one or more status indicators associated with an ultraviolet (UV) light source configured to supply light to a respective photolithography exposure apparatus of the one or more photolithography apparatuses;
      a graph region equivalent to the graph region, including one or more graphs displaying information relating to the one or more status indicators; and
      a filtering region equivalent to the filtering region, including one or more menu items selectable to control the information displayed in the status region and/or in the one or more graphs.

28. The system of example 27 wherein the computing device at the photolithography exposure facility is further configured to selectably display on the display screen, in response to a user selection of the one or more menu items, additional detailed data relating to the one or more light sources or to the one or more photolithography apparatuses including sub-wafer-level exposure data for the one or more light sources or the one or more photolithography apparatuses.

29. The system of example 28 wherein the computing device at the maintenance provider facility is not configured to receive or display sub-wafer-level exposure data for the one or more light sources or the one or more photolithography apparatuses.

30. The system of example 27 wherein the UV light source is a deep ultraviolet (DUV) light source.

The above-described implementations and other implementations are within the scope of the following claims.

1. A computing device at a photolithography exposure facility, the facility comprising one or more photolithography exposure apparatuses, the computing device comprising a display screen, the computing device being configured to display on the display screen:
a status region including one or more status indicators, each status indicator associated with an ultraviolet (UV) light source configured to supply light to a respective photolithography exposure apparatus of the one or more photolithography apparatuses;
a graph region including one or more graphs, each graph displaying information relating to the one or more status indicators; and
a filtering region including one or more menu items selectable to control the information displayed in the status region and/or in the one or more graphs.

2. The computing device of claim 1 wherein the computing device is configured to display status indicators comprising a first status indicator configured to indicate that the associated UV light source requires no action, a second status indicator configured to indicate that the performance of the associated UV light source should be monitored, and a third status indicator configured to indicate that the associated UV light source requires maintenance.

3. The computing device of claim 2 wherein the computing device is configured to display status indicators comprising a fourth status indicator configured to indicate that the status of the associated UV light source cannot be assessed.

4. The computing device of claim 1, wherein the computing device is configured to display on the display screen in the status region, for each of the one or more light source status indicators, a selectable set of subsystem status indicators, the subsystem status indicators associated with respective subsystems of the respective UV light source.

5. The computing device of claim 4 wherein the computing device is configured to display on the display screen in the filtering region one or more additional menu items selectable to control which subsystem status indicators are included in the selectable set of subsystem status indicators.

6. The computing device of claim 4 wherein the computing device is configured to display subsystem status indicators comprising a first subsystem status indicator configured to indicate that the associated subsystem requires no action, a second subsystem status indicator configured to indicate that the performance of the associated subsystem should be monitored, and a third subsystem status indicator configured to indicate that the associated subsystem requires maintenance, wherein the computing device is configured to display subsystem status indicators including a fourth subsystem status indicator configured to indicate that the status of the associated subsystem cannot be assessed.

7. (canceled)

8. The computing device of claim 1 wherein the facility comprises two or more photolithography exposure apparatuses and wherein the status region includes two or more status indicators.

9. A computing device at a photolithography exposure facility, the facility comprising one or more photolithography exposure apparatuses, the computing device comprising a display screen, the computing device being configured to display on the display screen:
a status region including one or more light source status indicators, each light source status indicator associated with an ultraviolet (UV) light source configured to supply light to a respective photolithography exposure apparatus of the one or more photolithography apparatuses.

10. The computing device of claim 9 wherein the computing device is configured to display on the display screen a graph region including one or more graphs, each graph displaying information relating to the one or more light source status indicators.

11. The computing device of claim 10 wherein the computing device is configured to display on the display screen a filtering region including one or more menu items selectable to control the information displayed in a graph of the one or more graphs.

12. The computing device of claim 11 wherein the one or more light source status indicators are a selected set of light source status indicators and the one or more menu items are selectable to control which light source status indicators are included in the selected set of light source status indicators.

13. The computing device of claim 9 wherein the computing device is configured to display on the display screen in the status region, for each of the one or more light source status indicators, a selectable set of subsystem status indicators, the subsystem status indicators associated with respective subsystems of the respective UV light source.

14. The computing device of claim 13 wherein the computing device is configured to display on the display screen in the filtering region one or more menu items selectable to control which subsystem status indicators are included in the selectable set of subsystem status indicators.

15. The computing device of claim 1 wherein the computing device is further configured to selectably display on the display screen, in response to a user selection of the one or more menu items, additional detailed data relating to the one or more light sources or to the one or more photolithography apparatuses.

16. The computing device of claim 15 wherein the additional detailed data comprises exposure data for the one or more light sources or the one or more photolithography apparatuses.

17-23. (canceled)

24. A computer program product comprising at least one non-transitory computer-readable storage medium having computer-executable program code instructions stored therein, the computer-executable program code instructions comprising program code instructions configured to, when executed by a processor of a computing system, cause the computing system to:
display a first status indicator of a group of status indicators within a first view of a user interface, the first status indicator configured to indicate that an ultraviolet (UV) light source requires no action, status indicators of the group of status indicators being indicative of the operation of the UV light source, the UV light source configured to supply UV light to a photolithography exposure apparatus;
in response to receipt of a first prediction using data relating one or more subsystems of a UV light source, the first prediction relating to the performance of the UV light source, change the display within the first view of the user interface from the first status indicator to a second status indicator of the group of status indicators, the second status indicator configured to indicate that the performance of the UV light source should be monitored; and
in response to receipt of a second prediction using data relating one or more subsystems of the UV light source, the second prediction relating to the performance of the UV light, change the display from the first status indicator or the second status indicator to a third status indicator within the first view of the user interface, the third status indicator configured to indicate that the UV light source requires maintenance.

25. The computer program product of claim 24 wherein the program code instructions are configured to, when executed by a processor of a computing system, cause the computing system to, in response receipt of information representing a status change relating to one or more subsystems of the UV light source, change the display within the first view of the user interface from the first status indicator, the second status indicator, or the third status indicator to a fourth status indicator of the group of status indicators, the fourth status indicator configured to indicate that the status of the UV light source cannot be assessed.

26. (canceled)

27. A system comprising:
a computing device at a photolithography exposure facility, the facility comprising one or more photolithography exposure apparatuses, the computing device comprising a display screen, the computing device being configured to display on the display screen:
a status region including one or more status indicators, each status indicator associated with an ultraviolet (UV) light source configured to supply light to a respective photolithography exposure apparatus of the one or more photolithography apparatuses;
a graph region including one or more graphs, each graph displaying information relating to the one or more status indicators; and
a filtering region including one or more menu items selectable to control the information displayed in the status region and/or in the one or more graphs; and, configured for communication in connection with the computing device at the photolithography exposure facility:
a computing device at a maintenance provider facility, the computing at the maintenance provider facility being configured to display on a display screen:
a status region equivalent to the status region, including the one or more status indicators associated with an ultraviolet (UV) light source configured to supply light to a respective photolithography exposure apparatus of the one or more photolithography apparatuses;
a graph region equivalent to the graph region, including one or more graphs displaying information relating to the one or more status indicators; and
a filtering region equivalent to the filtering region, including one or more menu items selectable to control the information displayed in the status region and/or in the one or more graphs.

28. The system of claim 27 wherein the computing device at the photolithography exposure facility is further configured to selectably display on the display screen, in response to a user selection of the one or more menu items, additional detailed data relating to the one or more light sources or to the one or more photolithography apparatuses including sub-wafer-level exposure data for the one or more light sources or the one or more photolithography apparatuses.

29. The system of claim 28 wherein the computing device at the maintenance provider facility is not configured to receive or display sub-wafer-level exposure data for the one or more light sources or the one or more photolithography apparatuses.

30. (canceled)
